(19) United States
(12) Patent Application Publication
(10) Pub. No.: US 2004/0036084 A1
(43) Pub. Date: Feb. 26, 2004

(54) Method and device for identifying the version of integrated circuits and use controling operating sequences

(76) Inventors: Christian Zimmermann, Tuebingen (DE); Manfred Kirschner, Stuttgart (DE); Juergen Eckhardt, Markgroeningen (DE); Beate Leibbrand, Muehlacker (DE); Thomas Mocken, Sersheim (DE); Axel Aue, Korntal-Muenchingen (DE)

Correspondence Address: KENYON & KENYON, ONE BROADWAY, NEW YORK, NY, 10004, US

(21) Appl. No.: 10/363,104

(22) PCT Filed: Aug. 18, 2001
(86) PCT No.: PCT/DE01/03170

(30) Foreign Application Priority Data
Aug. 31, 2000 (DE) 100431372

(51) Int. Cl. H01L 31/072

(52) U.S. Cl. 257/200

(57) ABSTRACT

A device and method for identifying the version of integrated circuits IC is described, an ID, which indicates the respective version of the integrated circuit IC, being written in the form of at least one individually settable binary signal in a register R and being readable from the register R. The integrated circuit IC is constructed from multiple mask levels M1 to M5, at least one possible conduction path L2 being introduced through all mask levels M1 to M5 of the integrated circuit for each settable binary signal BS. The binary signal is settable according to whether the at least one conduction path through all mask levels conducts or is interrupted, means being contained which write the binary signal, which is set via the at least one conduction path, into the register. This method and this device may also be used for controlling operating sequences by a control unit.

### BACKGROUND INFORMATION

The present invention relates to a device and a method for identifying the-version of integrated circuits, an ID which indicates the particular version of the integrated circuit being written in a register in the form of at least one individually settable binary signal, the ID being readable from the register, as well as a control unit and a method for use in the control of operating sequences, in particular for a motor vehicle, according to the preambles of the claims.

In the course of their development, but also during their mass production and/or in different series variants, integrated circuits experience circuit changes, redesigns, using which particular properties, in particular electrical properties, are changed. For the calibration and use in the series, it is important to know which version step is being used. Visual identification of the integrated circuit, through imprinting on the circuit itself or the packaging, for example, is often insufficient in this case or does not cover intermediate versions, in order to ensure a clear distinction.

For integrated circuits, in particular for engine control units, a device and a method are known, using which the version identification may be read out from the outside. In this case, the information about the version step, i.e., the corresponding design step, is permanently stored in a register, whose content may be read out via a serial interface using a read command. In this case, the content of this register may be set according to the version by being physically changed.

For this purpose, European Patent Application 0 791 836 A1 discloses an electronic device, which contains at least one device, in particular a circuit board, corresponding to the integrated circuits cited. This circuit board contains physically changeable memories, such as switches or jumpers, in connection with register cells. By setting the switch or jumper and thus connecting the register cells to ground or supply voltage, various pieces of information relating to the circuit board, such as the type, version number, and degree of modification, is manually, physically settable by the service engineer and may be read out via a serial interface.

If this method and/or this device was used for integrated circuits having multiple mask levels, a new version would have to be set manually for each change, regardless of the mask level. Automatic changes in the event of a mask change are not provided, due to which the method cited in the related art represents a high potential for error through incorrect setting.

The very simple ability to change by looking at the switch settings allows changes in the version identification even if the integrated circuit has not undergone any change at all. For security reasons, however, a certain unchangeable unambiguity in regard to the version identification is to be provided.

It has therefore been shown that the related art is not capable of providing optimal results in every regard. Therefore, a possibility is to be provided of identifying integrated circuits in such a way that the changes and the identification are reliably and uniquely assignable, while this identification ability is to have flexibility at comparatively low outlay.

### ADVANTAGES OF THE INVENTION

The present invention is directed to a device and a method for identifying the version for integrated circuits, an ID, which indicates the particular version of the integrated circuit, being written in a register in the form of at least one individually settable binary signal and being readable from the register. Since the integrated circuit according to the present invention is constructed from at least two mask levels, at least one possible conduction path is advantageously introduced through all mask levels of the integrated circuit for each settable binary signal, the binary signal being settable in that the at least one conduction path through all mask levels conducts or is interrupted, means expediently being contained which write the binary signal, which is set via the at least one conduction path, in the register.

In this case, it is advantageous that a change of the version identification is only possible through a change in the particular mask level affected. Since the change in the particular mask level is automatically accepted, the possibilities for error are restricted to the phase of layout preparation of the particular mask level and do not additionally exist in a subsequent independent version setting, since after the preparation of the particular mask level to be changed or multiple mask levels to be changed, a simple manual version change is not possible.

A further simplification results if the register is advantageously integrated into the integrated circuit itself and is connected to an interface, via which the ID may be read out from the register, the interface itself also being able to be contained in the integrated circuit. A very compact option for version identification, which is very flexible to handle, thus expediently results.

If, according to the present invention, the conduction path is equipped with a main contact in an uppermost mask level and a main contact in a lowermost mask level, different electrical potentials being applied to the main contacts, the binary signal may be generated and/or set very easily.

The conduction path is expediently connected to switching means, in particular a transistor, the switching means being connected in turn to the register and, as a function of whether the conduction path conducts or is interrupted, the switching means is advantageously controlled so that, as a function thereof, the appropriate binary signal is written in the register.

In this case, the control terminal of the switching means, in particular of the transistor, is connected, via a component, in particular a consumer or a power source, to a supply voltage, like the connection of the switching means, in particular the transistor, to the register, in order to write the appropriate binary signal in the particular register cell.

Furthermore, it is advantageous if, to increase the options for setting the binary signal, at least two possible conduction paths are connected to a logic means, in particular a logic gate, and the logic means is in turn connected to the register, the binary signal being written in the register via the connection of the logic means to the register.

In a preferred use of the device according to the present invention and the method according to the present invention, a control unit and a corresponding method are provided in which the control unit controls operating sequences, in particular in a vehicle, using selectable programs and/or data, means being contained which read out the register and analyze the ID, the program and/or data for controlling the operating sequences being selected and/or adapted in accordance with the version of the integrated circuit. The link of the correct program and/or data version to the particular hardware version of the integrated circuit is thus significantly simplified.

The outlay for changing the version identification in the event of redesigns is thus significantly reduced. Even the simplest changes may thus be uniquely identified.

The introduction of new design versions into, for example, the mass production of control units is significantly simplified. Using appropriate, self-adapting software, i.e., program and/or data versions, complex synchronization, in particular chronological synchronization, may be dispensed with during the introduction of new hardware and software versions. The probability of error during changeovers is thus drastically reduced.

Further advantages and advantageous embodiments result from the description and the claims.

### DRAWING

The present invention is described in the following on the basis of the figures illustrated in the drawing.

FIG. 1 shows a control unit for controlling operating sequences, in particular in vehicles, which contains an integrated circuit and a device according to the present invention.

FIG. 2, including FIGS. 2a and 2b, shows a section through an integrated circuit having multiple mask levels with the illustration of the conduction path according to the present invention, which is also referred to in the following as a lattice network.

FIG. 3 shows an example of a device according to the present invention having a lattice network, through which the appropriate binary signal is written in a register.

FIG. 4 shows a device according to the present invention having two lattice networks and a logic means, through which the possible adjustment variations for the binary signal are increased.

### DESCRIPTION OF THE EXEMPLARY EMBODIMENTS

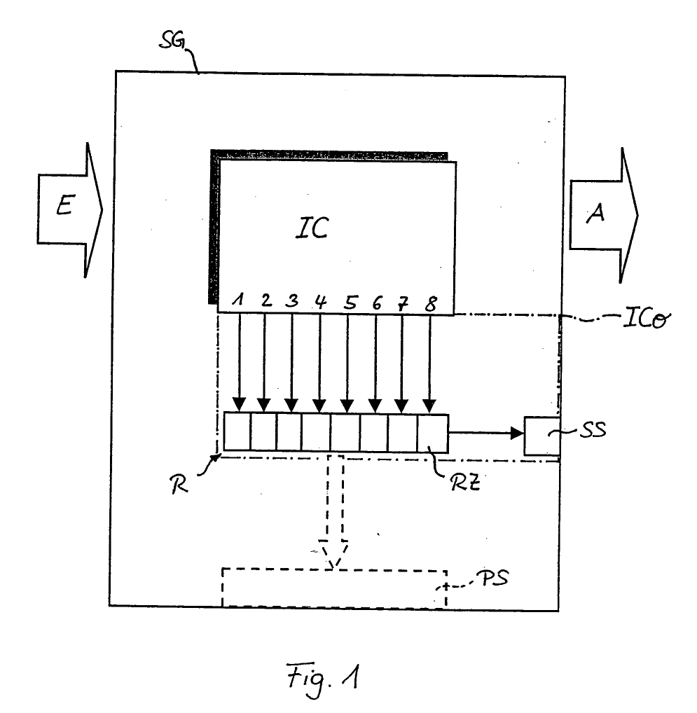

FIG. 1 schematically shows a control unit SG, which contains integrated circuit IC, whose version will be identified. This integrated circuit IC may be contained independently in the control unit or may be mounted into other components, such as in a processor component or another processor electronic system, as well as in interface cards or intelligent memory arrangements, which are in turn integrated into the control unit. Such an IC may also be contained in actuators or sensors.

Control unit SG in FIG. 1 is used in this case for controlling operating sequences, in particular in a vehicle. In the framework of this control or regulation of the operating sequences by control unit SG, input data E from sensors or further actuators and/or control units, for example, is read in and output variables A are also produced, in the framework of programs and/or data contained in the control unit, at sensors, actuators, or further control units.

These programs and/or data in the framework of the control and/or regulation of the operating sequences, which are also referred to in general in the following as software, are selected and/or adapted or changed in this case in accordance with the version of control unit SG and/or the integrated circuits contained therein. At the same time, the particular software version must correspond to the design step of the control unit, i.e., of the integrated circuit.

Eight binary signals BS, for example, are each written in a register cell RZ of register R via paths 1 to 8 of the integrated circuit. These 8 binary signals BS, for example, may then be read out from the register via a serial interface SS as an ID of the particular version. Optionally, the 8 binary signals, i.e., the 8 bits, may also be read out via a parallel interface PS.

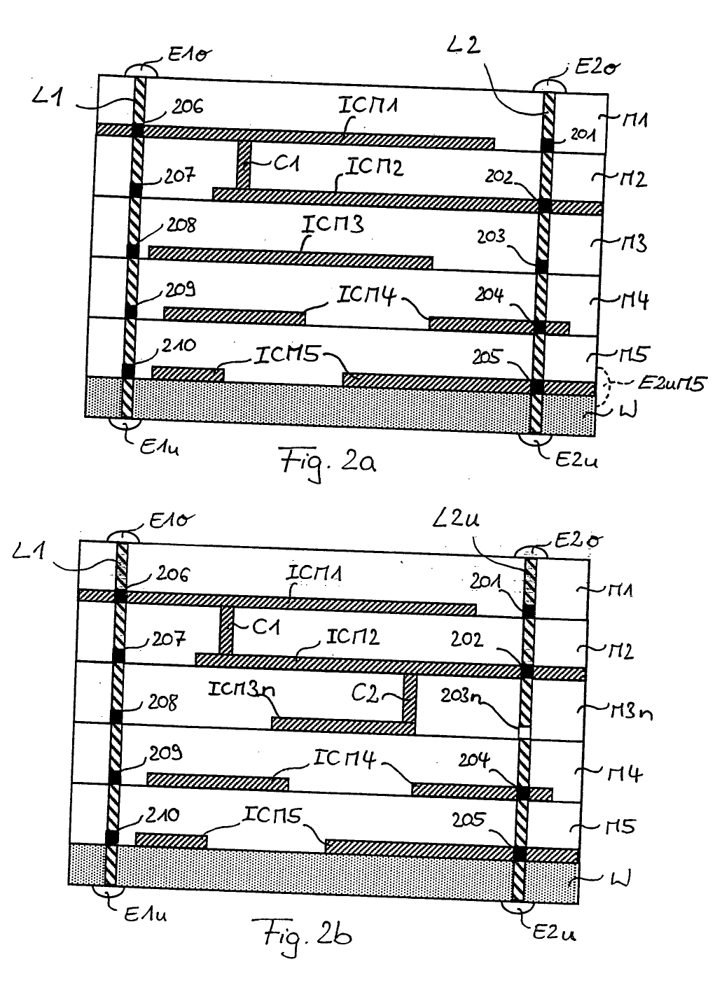

In a preferred embodiment, identified here by ICo, the register and/or interface SS or PS is optionally integrated into integrated circuit IC, whose version is to be identified. Through this compact embodiment, the ID is then permanently integrated with the register in circuit IC. In this case, particular binary signal BS of paths 1 to 8 corresponds to the particular signal of at least one conduction path and/or lattice network of the integrated circuit, which will be explained in greater detail in FIG. 2.

In the preferred embodiment of the present invention, a register which contains information about the design version of the integrated circuit is thus integrated into integrated circuit IC. The version identification, as, for example, 8-bit information, may be read out from the circuit via an interface in this case.

FIG. 2 includes FIGS. 2a and 2b, which each show a section through integrated circuit IC to illustrate the conduction paths and/or lattice networks. In this case, M1 to M5 represent different mask levels which are applied to a carrier, a wafer W. Parts of the integrated circuit, i.e., the paths of conductive materials in the particular insulating layers of mask levels M1 to M5, are represented using ICM1 to ICM5. These parts are made of, for example, metal, polysilicon, etc., In this case, a connection between two mask levels, in particular in the form of a conductive connection, i.e., a contact, is represented using C1. This connection, i.e., generally “via,” may also have a non-conductive character to compensate for thermal changes, for example.

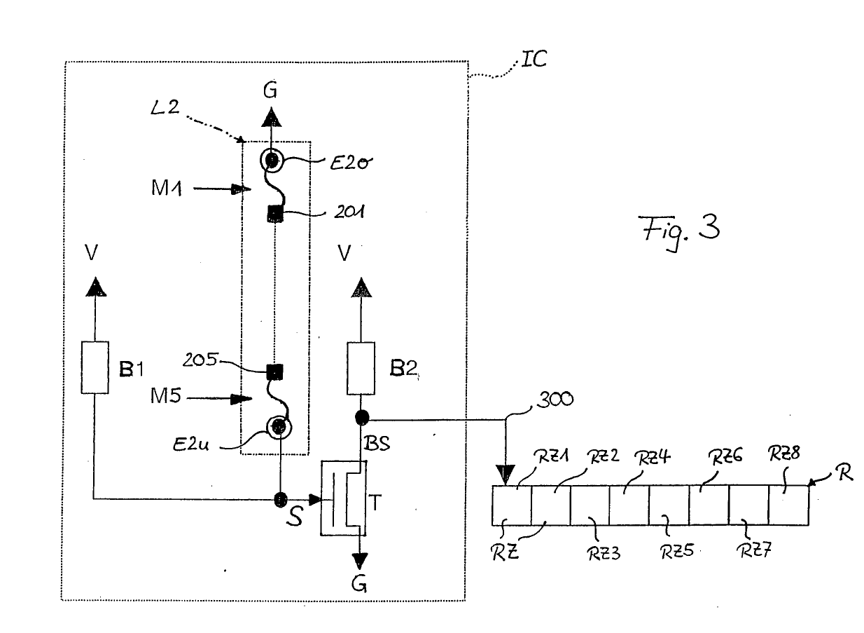

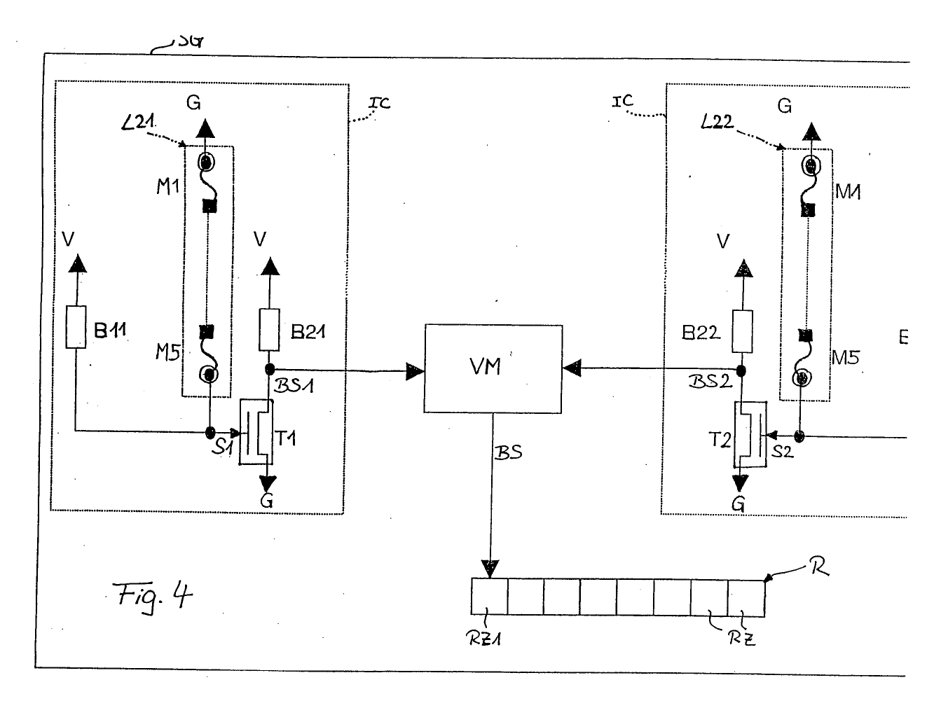

Two conduction paths L1 and L2 having contact windows 201 to 210 are incorporated in the respective mask levels in FIG. 2a. Lattice network L1 is enclosed in this case by upper main contact E1o and lower main contact E1u. In the same way, lattice network L2 is delimited by upper main contact E2o and lower main contact E2u. In this case, the main contacts may also lie directly in the particular uppermost and/or lowermost mask levels. This is indicated by main contact E2uM5. The contact windows, which lie in the particular uppermost and/or lowermost mask levels, 201 and 205 for L2 in this case, may in turn be made into main contacts and be connected to the circuit shown in FIGS. 3 and 4.

Lattice network L1 is implemented via contact windows 206 to 210 in mask levels M1 to M5. In the same way, lattice network L2 is connected via contact windows 201 to 205 of mask levels M1 to M5. If a voltage is applied to the lattice network in FIG. 2a, i.e., there are different potentials in relation to the upper and lower main contacts, a signal is generated in FIG. 2a for both lattice networks L1 and L2, since these networks are made conductive via the particular contact windows.

In FIG. 2b, a mask level M3 is now changed into M3n. In this new mask level, part of circuit ICM3n is now also new and/or changed in relation to ICM3, also through an additional connection C2, for example.

In order to identify this now different version of integrated circuit IC in FIG. 2b in relation to that in FIG. 2a, contact window 203 is opened in the framework of the layout design of new mask level M3n, represented by 203n, due to which network L2 is interrupted, represented as lattice network L2u. If a high-high identifier, i.e., a 1-1 identifier was represented in FIG. 2a as a binary-coded signal for networks L1 and L2, lattice network L1 is now still conductive in FIG. 2b, but lattice network L2 is interrupted as L2u, and a 1-0, i.e., high-low identifier exists for the IC. Therefore, the register information, i.e., the ID, is not determined solely by a metal mask, but rather by all relevant wiring masks (for example, metal, polysilicon, etc.). This is made possible according to the present invention by the use of such an arrangement as a lattice network, i.e., conduction path in the circuit, in which an electrically conductive connection is produced vertically through all wiring planes of the selection chip, i.e., integrated circuit IC. If other circuits, optical circuits, for example, are used, the conduction path according to the present invention may also be made of an optical and/or optically conductive connection through all planes of the optical circuit. Therefore, any conductor-based variant of such a lattice network, such as electrical, optical, or even in the framework of a waveguide, etc., is at least conceivable.

A circuitry for writing the information of a particular electrical lattice network in the particular register cell is indicated in FIG. 3. In this case, register R may preferably be housed inside integrated circuit IC or even outside the IC, in particular in control unit SG.

The lattice network from FIG. 2a and/or 2b, having an upper main contact E2o and a lower main contact E2u, is represented by L2. For clarity of the illustration, only contact windows 201 and 205 of conduction path L2 were illustrated. This also applies for both mask levels M1 and M5, in which the contacts lie.

One end of the conductive connection, i.e., lattice network L2, is connected to, for example, ground G in this case, while the other end leads to control terminal S of a switching means T, in particular to the control electrode of a transistor. In this case, a controlled switch is usable as a switching means in general.

In this exemplary embodiment, the control electrode is additionally connected via a component B1 to supply voltage V. This component B1 may be embodied in particular as a consumer, such as a pull-up resistor or even a current source as a pull-up current source for connection to a positive supply voltage.

The switching means generally has a potential difference applied to it in such a way that the switching means conducts or does not conduct as a function of the control terminal and therefore a binary signal is generated. One terminal of switching means T is connected in this case to ground G as a first potential, for example, the other terminal being connected via a component B2, which may be implemented comparably to component B1, to supply voltage potential, i.e., supply voltage V. The voltage at this output of the switching means, the drain of the transistor, for example, represents, as binary signal BS, one bit of the version ID, i.e., the version information. This binary signal as an identification signal is stored in digital form (0 or 1, i.e., low or high) as 1 bit in the identification register, register R, via connection 300; in this case, especially in register cell RZ1 of register cells RZ. The device integrated into the IC in FIG. 3 exists at least once for each register cell in accordance with the number of binary signals, i.e., bits in register R, in this case RZ1 to RZ8, i.e., in this example, 8 times for one byte.

As a function of whether the vertical connection, i.e., the lattice network, exists in conductive form or, due to an interruption in one or more mask levels, does not exist or does not conduct, a binary signal corresponding to 0 or 1, i.e., low or high is displayed and/or written in register R via component B2, in particular a consumer, such as a resistor, and switching means T, in particular a transistor. If a mask level, i.e., a mask such as M3n in FIG. 2 changes through a redesign, it is sufficient to change the contact window of the particular mask in such a way that the desired binary version, i.e., corresponding binary signal BS, exists in register R as the identification register. In this way, the information of the individual register cells, 8 in this case, may be read out as the ID of the particular version.

The device thus corresponds to a series circuit of n switches or n fuses corresponding to number n of the mask levels, i.e., n=5 here, the conductivity of the number of all contacts being analyzed. Number n of necessary switches and/or fuses is equal to the number of mask levels in this case. It is therefore sufficient to interrupt the lattice network in one mask level to convert the corresponding bit, i.e., binary signal.

Depending on the necessary binary resolution of the version information, i.e., the ID, 8 bits here, for example, the structures are to be implemented multiple times, 8 times here, for example. Each implementation corresponds to one binary signal BS, i.e., bit of the version information in this case.

The device described allows any change, which may even only affect one mask level or one mask, to be identified in register R as the identification register. Therefore, only the contact windows of the mask which are modified to perform the change in any case must be changed. Due to the vertical arrangement of the contacts and/or contact windows through all planes, it is sufficient to interrupt the connection in one mask level in order to convert, i.e., change one or more binary signals, i.e., bits. In this way, the outlay for changing the version identification in the event of redesigns is significantly reduced and even the simplest changes may thus be identified uniquely and relatively unchangeably in regard to the particular version.

Using the structure, i.e., device suggested in FIG. 3, by introducing an interruption in the conduction path, i.e., lattice network in a mask level, the corresponding binary signal and/or identification signal may always be changed only in one direction, in this case, for example, from high to low or from 1 to 0. Therefore, not all theoretically possible binary versions of binary signal (identification signal) BS and/or of the overall ID are available for the device in FIG. 3.

In order to remove this restriction, the embodiment of the present invention described in FIG. 4 may be used. If, for example, the binary signals of two lattice networks L21 and L22 are linked via a logic means VM, changes in the corresponding binary signals in both directions are possible.

For this purpose, a lattice network L21 having a control terminal S1 and a switching means T1 is illustrated in FIG. 4. Control terminal S1 is connected via a component B11 to supply voltage V. The output of switching means T1, in particular a transistor, is also connected via a component B21 to supply voltage V.

In accordance with a conductive connection through mask levels M1 to M5 or interruptions made therein (conduction path, i.e., lattice network), a binary signal BS1 is supplied to logic means VM. For a lattice network L22, which is also connected to a control terminal S2, which is simultaneously connected via a component B12 to supply voltage V, is used. Through control terminal S2 of switching means T2, in particular a transistor, the connection from ground G via the output of switching means T2 and component B22 to supply voltage V is opened or closed. In this way, a binary signal BS2 is correspondingly input to logic means VM.

By duplicating the lattice network and subsequent processing of both resulting identification signals, i.e., binary signals BS1 and BS2 by a logic means VM, in particular a logic gate, it becomes possible to reset a binary signal or identity bit, which has been changed from 1 to 0 or high to low, back to 1 and vice versa. For an 8-bit-wide identification register R, the number of changes which may be represented expands, in relation to the most unfavorable case of 8 according to FIG. 3, to a total of 256 changes.

As already mentioned in the framework of the description of FIG. 1, the devices having the particular lattice networks (e.g., L21 and L22), which provide the binary signals (e.g., BS1 and BS2) and the particular logic means (VM), which provides particular final binary signal BS, which is written in register cells RZ of identification register R, and register R itself are advantageously integrated on and/or in integrated circuit IC in this case.

The device illustrated in FIG. 4 describes register cell RZ1 using binary signal BS. The remaining, comparable devices for RZ2 to RZ8 are not shown for reasons of clarity.

Logic means VM may be implemented in particular as logic gates of a great variety of logic operations in this case, as a negated exclusive OR, for example, as shown in the following in Table 1:

TABLE 1

| | Binary | Binary | Binary |
|---|---|---|---|
| | signal BS1 | signal BS2 | signal BS |
| Original version | 1 | 1 | 1 |
| 1^{st} change/version 2 | 0 | 1 | 0 |
| 2^{nd} change/version 3 | 0 | 0 | 1 |
| Not used | 1 | 0 | x |

In this case, the original state is, for example, a high signal (1) from BS1 and BS2, which then also results in a high signal of identification signal BS. The first change of the integrated circuit results in a low signal (0) from BS1, through which a 0 then results in register cell RZ1, i.e., binary signal BS. The second change of the integrated circuit then results in a binary signal BS2 equal to 0. In this way, for a negated exclusive OR logic, a 1 of binary signal BS results, which is written in register cell RZ1. The combination of binary signals BS1 and BS210 is not used in this case.

To link both signals BS1 and BS2 in the framework of a logic gate, all known gate functions, i.e., AND, OR, exclusive OR, and the negated variants, etc., are conceivable. An individual logic operation is possible if logic means VM has its own intelligence or special assignment tables and/or assignment rules to generate an output signal BS.

Using the embodiments of the present invention illustrated in the figures, it is possible, for example, to define systems, such as control unit SG in this case, which automatically adapt themselves to the particular version of the integrated circuit. For example, branches may be incorporated into the corresponding programs and/or data sets so that different program parts are executed as a function of the version number read out, i.e., the version ID.

Linkage of the correct software version to the particular hardware version of the integrated circuit would be significantly simplified, as in a control unit SG corresponding to FIG. 1 for controlling operating sequences, in particular in a vehicle, which has information inputs E and information outputs A and controls and/or regulates operating sequences in accordance with particular programs and/or program parts or data sets and/or parts of data sets. In accordance with the particular regulation procedure, the program parts and/or data sets necessary and/or optimal for the particular regulation may be selected and/or automatically adapted from multiple programs and/or data. Therefore, it is sufficient to simply introduce the integrated circuit having its unchangeable version identification to automatically select an optimized software version for it. Using the example of a vehicle, from a pool of software versions for transmission control, engine control, and suspension control, such as ABS, ACC, ESP, etc., the correlation of hardware version and software version may be quasi-automatically produced by the unique identification according to the present invention. The same also applies, of course, for the hardware and software of other control and regulation tasks inside and even outside a vehicle.

Thus, the introduction of new design versions into the mass manufacture of control units is significantly simplified. Using corresponding software which adapts itself, complex chronological synchronization during the introduction of new hardware and software versions may be dispensed with. The probability of error during changeovers to new software versions correlated with the particular hardware version of the integrated circuit may be greatly reduced at the same time.

At the same time, the device according to the present invention advantageously only requires a relatively small area in the control unit or on the integrated circuit due to its simple construction, through which the outlay as a whole remains very low.

What is claimed is:

1. A device for identifying the version of integrated circuits, an ID, which indicates the particular version of the integrated circuit, being written in a register in the form of at least one individually settable binary signal, said ID being readable from the register,
wherein the integrated circuit is constructed from multiple mask levels and at least one possible conduction path is introduced through all mask levels of the integrated circuit for each settable binary signal, the binary signal being settable according to whether the at least one conduction path through all mask levels conducts or is interrupted, means being contained which write the binary signal, which has been set via the at least one conduction path, into the register.

2. The device as recited in claim 1,
wherein the register is integrated into the integrated circuit and is connected to an interface, in particular a serial interface, via which the ID may be read out of the register.

3. The device as recited in claim 1,
wherein the conduction path has a main contact in an uppermost mask level and a main contact in a lowermost mask level, different electrical potentials being applied to the main contacts.

4. The device as recited in claim 1,
wherein the conduction path is connected to a switching means, in particular a transistor, and the switching means is connected to the register, the switching means being controlled as a function of whether the conduction path conducts or is interrupted, and a corresponding binary signal being written in the register via the connection as a function thereof.

5. The device as recited in claim 4,
wherein the switching means is implemented as a transistor, and a control terminal of the transistor is connected via a component, in particular a consumer or a power source, to a supply voltage.

6. The device as recited in claim 4,
wherein the switching means is implemented as a transistor, and the connection of the transistor to the register is additionally connected via a component, in particular a consumer or a power source, to a supply voltage.

7. The device as recited in claim 1,
wherein at least two possible conduction paths are connected to a logic means, in particular a logic gate, and the logic means is connected to the register, the binary signal being written in the register via the connection of the logic means to the register.

8. A control unit, which contains a device according to claim 1, the control unit controlling operating sequences, in particular in a vehicle, using selectable programs and/or data,
wherein the unit contains means which read out the register and analyze the ID and, in accordance with the version of the integrated circuit, select and/or adapt the programs and/or data for controlling the operating sequences.

9. A method of identifying the version of integrated circuits, an ID, which indicates the particular version of the integrated circuit, being written in a register in the form of at least one individually settable binary signal, the ID being readable from the register,
wherein the integrated circuit is constructed from multiple mask levels, and at least one possible conduction path is produced through all mask levels of the integrated circuit for each settable binary signal, the binary signal being set according to whether the at least one conduction path through all mask levels is rendered conductive or is interrupted, the binary signal set via the at least one conduction path being written in the register.

10. The method as recited in claim 9, the integrated circuit being used to control operating sequences, in particular in a vehicle, using selectable programs and/or data,
wherein the ID is read from the register and analyzed, and programs and/or data for controlling the operating sequences are selected and/or adapted as a function of the version of the integrated circuit corresponding to the ID.
